(19) United States
(12) Patent Application Publication
(10) Pub. No.: US 2021/0307221 A1
(43) Pub. Date: Sep. 30, 2021

(54) SHIELD STRUCTURE AND ELECTRONIC DEVICE

(71) Applicant: SHARP KABUSHIKI KAISHA, Sakai City (JP)

(72) Inventor: SHINGO NAKAGAWA, Sakai City (JP)

(21) Appl. No.: 17/213,116

(22) Filed: Mar. 25, 2021

(30) Foreign Application Priority Data
Mar. 26, 2020 (JP) 2020-056375

(51) Int. Cl. H05K 9/00; H01L 23/552; H01L 23/433; H05K 7/20

(52) U.S. Cl. CPC H05K 9/0032; H05K 7/20472; H01L 23/433; H01L 23/552

(57) ABSTRACT

A shield structure includes: a shield frame electrically conductive and disposed around an electronic component mounted on a board top face of a circuit board, the shield frame having a lower end positioned toward, and secured to, the board top face to conduct electricity to the circuit board, and an upper end opened, and positioned across from the lower end; and an electrically conductive plate provided to the upper end of the shield frame, the electrically conductive plate including a thin area thinned across from the electronic component and the shield frame, and electrically connected to the shield frame through the thin area.

### CROSS-REFERENCE TO RELATED APPLICATION

The present application claims priority from Japanese Application JP2020-056375, the content to which is hereby incorporated by reference into this application.

### BACKGROUND OF THE INVENTION

### 1. Field of the Invention

The present invention relates to a shield structure shielding an electronic component mounted on a circuit board, and an electronic device including the shield structure.

### 2. Description of the Related Art

A typical shield structure known in the art and cited in, for example, WO 2006/035542, prevents release and entry of an electromagnetic wave (noise) from and into an electronic component.

FIG. 6 is a cross-sectional view illustrating an example of an electronic device in a typical shield structure. As illustrated in FIG. 6, an electronic device 101 includes: a casing 102 made of resin; a shield frame 105a disposed around an electronic component 104 on a circuit board 103; a shield cover 105b covering an opening on top of the shield frame 105a; and a metal plate 106 such as a radiating plate. The electronic device 101 covers the electronic component 104 with the shield frame 105a and the shield cover 105b to block an electromagnetic wave.

### SUMMARY OF THE INVENTION

In the typical shield structure, the casing 102 unfortunately increases in thickness. In the electronic device 101, the shield cover 105b is disposed above the circuit board 103. Between the electronic component 104 and the shield cover 105b, a certain clearance or a flexible sealing material needs to be provided to ensure strength of the electronic device 101. Similarly, also between the shield cover 105b and the metal plate 106, a certain clearance or a flexible sealing material needs to be provided to ensure strength of the electronic device 101. Because the clearance or a space for the flexible sealing material needs to be left, the electronic device 101 in the typical shield structure increases in thickness-wise dimension and becomes thicker.

In view of the above typical problem, an aspect of the present invention intends to provide a shield structure capable of reducing a size of an electronic device to be mounted.

A shield structure according an aspect of the present invention includes: a shield frame electrically conductive and disposed around an electronic component mounted on a board top face of a circuit board, the shield frame having (i) a lower end positioned toward, and secured to, the board top face to conduct electricity to the circuit board, and (ii) an upper end opened, and positioned across from the lower end; and an electrically conductive plate provided to the upper end of the shield frame, the electrically conductive plate (i) including a thin area thinned across from the electronic component and the shield frame, and (ii) electrically connected to the shield frame through the thin area.

An aspect of the present invention can provide a shield structure which allows for downsizing of a device to be mounted.

### BRIEF DESCRIPTION OF THE DRAWINGS

FIG. 1 is a cross-sectional view illustrating an electronic device according to a first embodiment of the present invention;

FIG. 2 is a cross-sectional view illustrating a modification of the electronic device;

FIG. 3 is a cross-sectional view illustrating another modification of the electronic device;

FIG. 4 is a cross-sectional view illustrating the electronic device in FIG. 3 with solder removed from a connection between a shield frame and a metal plate;

FIG. 5 is a cross-sectional view illustrating an electronic device according to a second embodiment of the present invention; and

FIG. 6 is a cross-sectional view illustrating an example of an electronic device in a typical shield structure.

### DETAILED DESCRIPTION OF THE INVENTION

### First Embodiment

Described below is an embodiment of the present invention, with reference to FIG. 1. This embodiment describes an electronic device including a shield structure according to the present invention. Note that, unless otherwise specifically described, features described in the embodiments below and a combination of the features do not intend to limit the scope of the present invention only to the features. Hence, the features and the combination are mare examples.

Configuration of Electronic Device

Described first is a configuration of an electronic device according to a first embodiment of the present invention. FIG. 1 is a cross-sectional view illustrating an electronic device 1 according to this embodiment. As illustrated in FIG. 1, the electronic device 1 includes: a casing 2; a circuit board 3, an electronic component 4; a shield frame 5; and a metal plate (an electrically conductive plate) 6. The circuit board 3, the electronic component 4, the shield frame 5, and the metal plate 6 are arranged inside the casing 2.

The electronic device 1 is, for example, a smartphone, a tablet terminal, a wireless local area network (WLAN), or a wireless communications device outputting a broadcast wave. The shield structure to be described later is applied to those electronic devices, such that the electronic devices can be kept from problems including interference of an electromagnetic wave from the electronic component 4.

The casing 2 is an exterior panel made of, for example, synthetic resin. The casing 2 may include a plurality of components. For example, the casing 2 may include a lower casing and an upper casing separable from each other. The lower casing and the upper casing may fit together.

The circuit board 3 is a printed board provided with wires for an electronic circuit. The circuit board 3 has a board top face 31 on which the electronic component 4 is mounted with, for example, solder.

The electronic component 4 is a component of every kind to be mounted on the circuit board 3. Examples of the electronic component 4 include an integrated circuit (IC) chip and a passive component. Moreover, the electronic component 4 may also be, for example, a power supply IC, a central processing unit (CPU), a memory, or a wireless circuit. The electronic component 4 may not only be a single component, but also be a combination of a plurality of components.

The shield frame 5 is a frame member formed of an electrically conductive material such as metal capable of blocking an electromagnetic wave. The shield frame 5 is disposed around the electronic component 4. In this embodiment, the shield frame 5 is rectangular in planar view. All four sides of the shield frame 5 surrounding the electronic component 4 are each provided with a side wall 51. The shield frame 5 (the side wall 51) has a lower end toward the board top face 31. The lower end is joined to the board top face 31 with solder 7 to conduct electricity to a ground pattern formed on the board top face 31. Moreover, the shield fame 5 includes an internal flange 52 provided to an upper end, of the shield frame 5, across from the lower end. The internal flange 52 protrudes toward an inside of the shield frame 5. The upper end of the shield frame 5 other than the internal flange 52 is open. The shield frame 5 includes an opening 53 formed to be positioned across from the electronic component 4.

The metal plate 6 is a radiating plate or a reinforcing plate provided to the casing 2 of the electronic device 1. The shield fame 6 is provided to the upper end of the shield frame to block the opening 53. The metal plate 6 includes a thin area 61 recessed and thinned across from the electronic component 4 and the shield fame 5. This thin area 61 is formed by, for example, cutting or stamping.

The metal plate 6 includes a protrusion 62 provided to the thin area 61 and making contact with the internal flange 52 of the shield frame 5. The protrusion 62 is continuously formed on the thin area 61, and positioned across from the internal flange 52. The protrusion 62 makes contact with the internal flange 52 of the shield frame 5, such that the shield frame 5 and the metal plate 6 are electrically connected together.

Advantageous Effects of Electronic Device

Described next are advantageous effects of the electronic device 1 according to this embodiment. In the shield structure of the electronic device 1, the shield frame 5 and the metal plate 6 cover the electronic component 4 mounted on the circuit board 3 to block an electromagnetic wave.

Here, in the shield structure of the electronic device 1, the upper end of the shield frame 5 is housed in the recess forming the thin area 61 of the metal plate 6, and, in the thin area 61, the shield frame 5 and the metal plate 6 are electrically connected together. Hence, the metal plate 6 is positioned closer to the circuit board 3 by the reduced thickness of the metal plate 6. Such a feature makes it possible to decrease the casing 2 of the electronic device 1 in thickness-wise dimension, and to reduce the electronic device 1 in size (in thickness).

Moreover, in the shield structure of the electronic device 1, the casing 2 of the electronic device 1 is provided with the metal plate 6, including a radiating plate or a reinforcing plate, functioning as a conventional shield cover. Such a feature eliminates the need of a shield cover, making it possible to further reduce the electronic device 1 in size (in thickness). Furthermore, the feature reduces the number of components, making it possible to lower production costs of the electronic device 1. In addition, the shield frame 5 and the metal plate 6 are connected together. Such a feature makes it possible to propagate heat of the electronic component 4 from the shield frame 5 to the metal plate 6, and to dissipate the heat efficiently.

As can be seen, the shield structure of the electronic device 1 includes the shield frame 5 electrically conductive and disposed around the electronic component 4 mounted on the board top face 31 of the circuit board 3. The shield frame 5 has (i) a lower end positioned toward, and secured to, the board top face 11 to conduct electricity to the circuit board 3, and (ii) an upper end opened, and positioned across from the lower end. Moreover, the shield structure of the electronic device 1 further includes the metal plate 6 provided to the upper end of the shield frame 5. The metal plate 6 (i) includes the thin area 61 thinned across from the electronic component 4 and the shield frame 5, and (ii) electrically connected to the shield frame 5 through the thin area 61.

In the electronic device 1, the metal plate 6 includes the thin area 61 thinned across from the circuit board 3 and the shield frame 5. In this thin area 61, the shield frame 5 and the metal plate 6 are electrically connected together. Hence, the metal plate 6 can be positioned closer to the circuit board 3 by the reduced thickness of the metal plate 6.

Hence, this embodiment makes it possible to decrease the electronic device 1 in thickness-wise dimension, and to reduce the electronic device 1 in size (in thickness).

First Modification

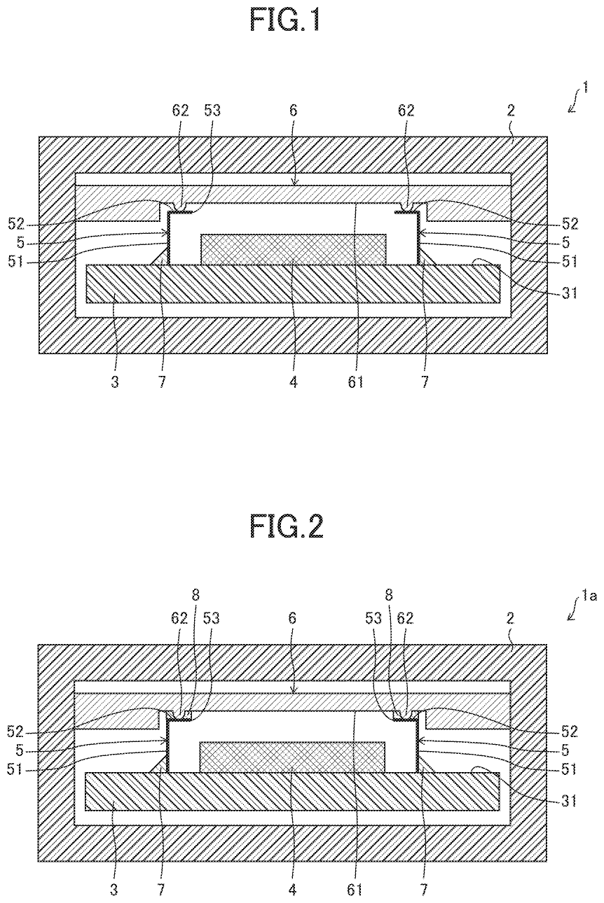

FIG. 2 is a cross-sectional view illustrating a modification of the electronic device 1 in FIG. 1. An electronic device 1a illustrated in FIG. 2 is mainly different from the electronic device 1 in that a connection electrically connecting the shield frame 5 and the metal plate 6 together is provided with a flexible member 8 which is electrically conductive.

The flexible member 8, which is electrically conductive and cushioning, is a sealing member such as a gasket. The flexible member 8 provided to cover the connection between the shield frame 5 and the metal plate 6 can maintain electrical connection between the shield frame 5 and the metal plate 6, even if, for example, the shield frame 5 or the metal plate 6 becomes distorted. The flexible material 8 also reduces the risk of a gap to open in the connection between the shield frame 5 and the metal plate 6, making it possible to maintain an advantageous effect of blocking an electromagnetic wave.

Hence, in the electronic device 1a, even if the shield frame 5 or the metal plate 6 becomes distorted, the flexible member 8 absorbs the distortion, making it possible to maintain good connection between the shield frame 5 and the metal plate 6.

Second Modification

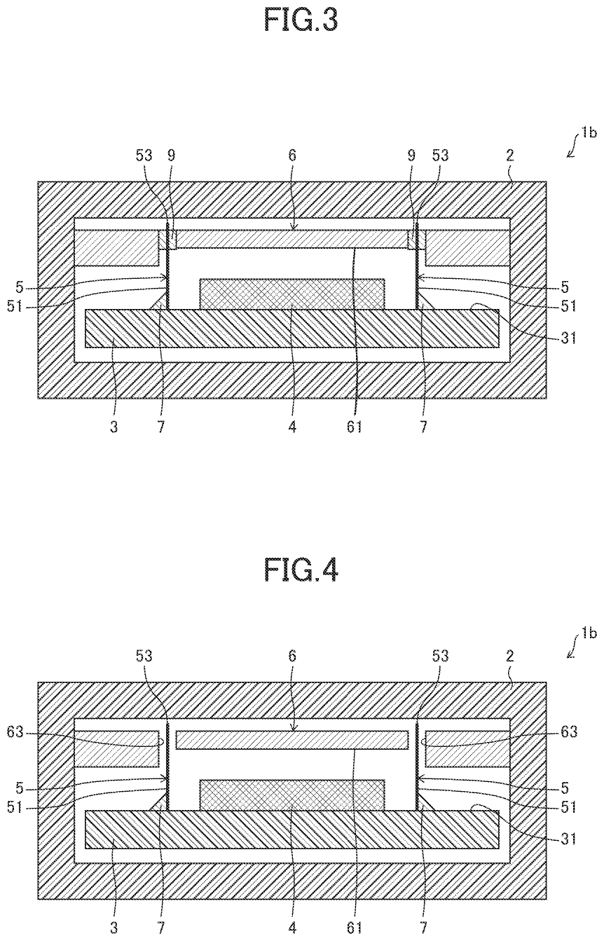

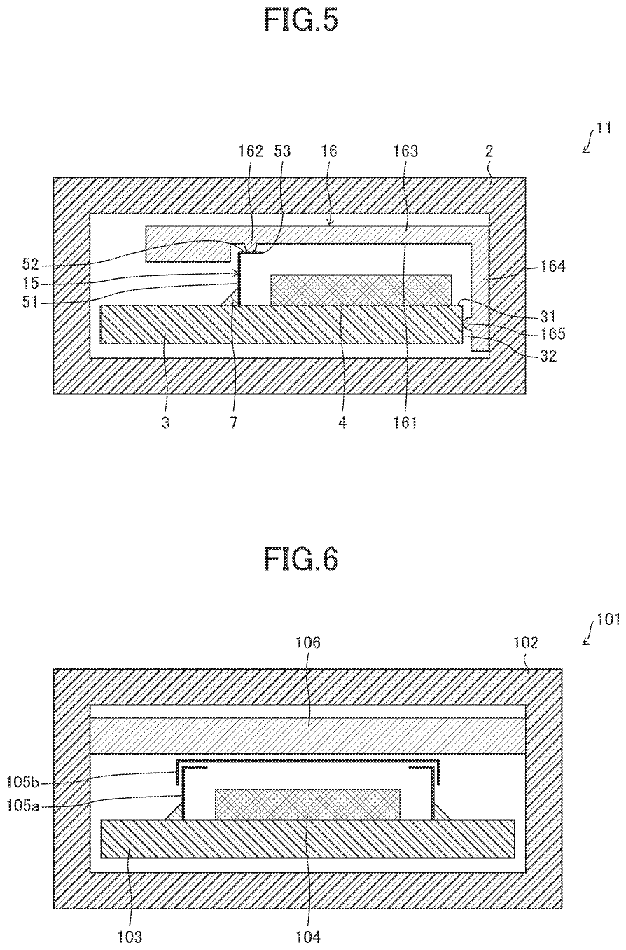

FIG. 3 is a cross-sectional view illustrating another modification of the electronic device 1 in FIG. 1. FIG. 4 is a cross-sectional view illustrating an electronic device 1b in FIG. 3 with solder 9 removed from a connection between the shield frame 5 and the metal plate 6. The electronic device 1b illustrated in FIGS. 3 and 4 is mainly different from the electronic device 1 in that, in a connection electrically connecting the shield frame 5 and the metal plate 6 together, an upper end of the shield frame 5 is fixed in a clearance formed in the metal plate 6.

The electronic device 1b has no internal flange 52 to be formed on the upper end of the shield frame 5, and the shield frame 5 includes the side wall 51. Moreover, the thin area 61 of the metal plate 6 includes a clearance 63 in which the upper end of the shield frame 5 (the side wall 51) can be inserted. In the connection between the shield frame 5 and the metal plate 6, the upper end of the shield frame 5 is inserted in the clearance 63 formed in the metal plate 6, and the shield frame 5 is fixed in the clearance 63 with the solder 9.

Such features make it possible to maintain electrical connection between the shield frame 5 and the metal plate 6, even if, for example, the shield frame 5 or the metal plate 6 becomes distorted. The features also reduce the risk of a gap to open in the connection between the shield frame 5 and the metal plate 6, making it possible to maintain an advantageous effect of blocking an electromagnetic wave.

Hence, in the electronic device 1b, even if the shield frame 5 or the metal plate 6 becomes distorted, the solder 9 can maintain good connection between the shield frame 5 and the metal plate 6. Note that, instead of the solder 9, an electrically conductive adhesive may be used to fix the shield frame 5 in the clearance 63 of the metal plate 6.

### Second Embodiment

Described below is another embodiment of the present invention, with reference to FIG. 5. Note that, for the sake of convenience for description, identical reference signs are used to denote identical or substantially identical components between the first embodiment and this embodiment, and therefore will not be elaborated upon.

Configuration of Electronic Device

Described first is a configuration of an electronic device according to a second embodiment of the present invention. FIG. 5 is a cross-sectional view illustrating an electronic device 11 according to this embodiment. As illustrated in FIG. 5, the electronic device 11 includes: the casing 2; the circuit board 3, the electronic component 4; a shield frame 15; and a metal plate (an electrically conductive plate) 16. The electronic device 11 is mainly different from the electronic device 1 according to the first embodiment in that the shield frame 15 has a side end (a side) open, and the metal plate 16 is L-shaped.

The shield frame 15 is disposed around the electronic component 4. In this embodiment, the shield frame 15 is rectangular in planar view. One of the four sides of the shield frame 15 is open, and the other three sides surrounding the electronic component 4 are each provided with the side wall 51.

In side view, the metal plate 16 is formed to be L-shaped to include: a board-top-face opposing portion 163 positioned across from the board top face 31 of the circuit board 3; and a board-side-face opposing portion 164 positioned across from one of board side faces 32 of the circuit board 3. The metal plate 16 is formed to include a thin area 161 over the board-top-face opposing portion 163 and the board-side-face opposing portion 164. Such features make it possible to decrease the casing 2 of the electronic device 11 in thickness-wise dimension and width-wise dimension.

The board-top-face opposing portion 163 is provided to block an upper end of the shield frame 15. The board-top-face opposing portion 163 includes a first protrusion 162 provided to the thin area 161 and making contact with the internal flange 52 of the shield frame 15. The first protrusion 162 is continuously formed on the thin area 161, and positioned across from the internal flange 52.

The board-side-face opposing portion 164 is provided to block an opened side end of the shield frame 15. That is, each end face, of two of the side walls 51, positioned toward the opened side end of the shield frame 15 is connected to the board-side-face opposing portion 164. Moreover, the board-side-face opposing portion 164 includes a second protrusion 165 provided to the thin area 161 across from a board side face 32 of the circuit board 3, and making contact with the board side face 32. The second protrusion 165 is continuously formed on the thin area 161, and positioned across from the board side face 32.

Advantageous Effects of Electronic Device

Described next are advantageous effects of the electronic device 11 according to this embodiment. When the shield frame 5 surround all the edges of the electronic component 4 as seen the above electronic device 1, the electronic component 4 needs to be mounted away from an end of the circuit board 3, so that a space is reliably left around the electronic component 4 to accommodate the side wall 51 of the shield frame 5.

In contrast, in the electronic device 11, the shield frame 15 has a side end opening across from the board-side-face opposing portion 164. Such a feature eliminates a need of a space to be left to accommodate the side wall 51 at the opening side wall, making it possible to mount the electronic component 4 close to the end of the circuit board 3.

Hence, this embodiment makes it possible to decrease the electronic device 11 in width-wise direction as well as in thickness-wise dimension.

Summary

A shield structure according a first aspect of the present invention includes: a shield frame electrically conductive and disposed around an electronic component mounted on a board top face of a circuit board, the shield frame having (i) a lower end positioned toward, and secured to, the board top face to conduct electricity to the circuit board, and (ii) an upper end opened, and positioned across from the lower end; and an electrically conductive plate (the metal plate 6, 16) provided to the upper end of the shield frame, the electrically conductive plate (i) including a thin area thinned across from the electronic component and the shield frame, and (ii) electrically connected to the shield frame through the thin area.

In the above configuration, the electrically conductive plate includes the thin area thinned across from the circuit board and the shield frame. In this thin area, the shield frame and the electrically conductive plate are electrically connected together. Hence, the electrically conductive plate can be positioned closer to the circuit board by the reduced thickness of the electrically conductive plate. Such a feature makes it possible to decrease the electronic device in thickness-wise dimension, and to reduce the electronic device in size (in thickness).

A second aspect of the present invention is directed to the shield structure according to the first aspect. The electrically conductive plate may be a radiating plate or a reinforcing plate provided to a casing of the electronic device in the shield structure.

In the above configuration, the radiating plate or the reinforcing plate provided to the casing of the electronic device can function as a conventional shield cover. Such a feature eliminates the need of a shield cover, making it possible to further reduce the electronic device in size (in thickness). Furthermore, the feature reduces the number of components, making it possible to lower production costs of the electronic device. In addition, the shield frame and the electrically conductive plate such as a radiating plate are connected together. Such a feature makes it possible to propagate heat of the electronic component from the shield frame to the electrically conductive plate, and to dissipate the heat efficiently.

A third aspect of the present invention is directed to the shield structure according to the first or second aspect. The electrically conductive plate may include a board-side-face opposing portion positioned across from one of board side faces of the circuit board, and the shield frame may have a side end opened, and positioned across from the board-side-face opposing portion, the side end being connected to the board-side-face opposing portion.

For example, when the shield frame surrounds all the edges of the electronic component, the electronic component needs to be mounted away from the end of the circuit board so that a space is left around the electronic component to accommodate the shield frame. In the above configuration, the shield frame has a side end opening across from the board-side-face opposing portion. Such a feature eliminates a need of a space to be left to accommodate the shield frame at the opening side wall, making it possible to mount the electronic component close to the end of the circuit board. Hence, the feature makes it possible to decrease the electronic device in width-wise dimension, and to reduce the electronic device in size.

A fourth aspect of the present invention is directed to the shield structure according to any one of the first to third aspects. The shield structure may further include a conductive flexible member provided to a connection electrically connecting the shield frame and the electrically conducting plate together.

In the above configuration, the flexible member can maintain electrical connection between the shield frame and the electrically conductive plate, even if, for example, the shield frame or the electrically conductive plate becomes distorted. The flexible member also reduces the risk of a gap to open in the connection between the shield frame and the electrically conductive plate, making it possible to maintain an advantageous effect of blocking an electromagnetic wave.

A fifth aspect of the present invention is directed to the shield structure according to any one of the first to third aspects. In a connection electrically connecting the shield frame and the electrically conductive plate together, the upper end of the shield frame may be inserted in a clearance formed in the electrically conductive plate, and the shield frame may be fixed in the clearance with solder or a conductive adhesive.

In the above configuration, the above feature can maintain electrical connection between the shield frame and the electrically conductive plate, even if, for example, the shield frame or the electrically conductive plate becomes distorted. The feature also reduces the risk of a gap to open in the connection between the shield frame and the electrically conductive plate, making it possible to maintain an advantageous effect of blocking an electromagnetic wave.

An electronic device according to a sixth aspect of the present invention is in the shield structure according to any one of the first to fifth aspects.

The above configuration makes it possible to decrease the electronic device in thickness-wise dimension, and to reduce the electronic device in size (in thickness).

While there have been described what are at present considered to be certain embodiments of the invention, it will be understood that various modifications may be made thereto, and it is intended that the appended claim cover all such modifications as fall within the true spirit and scope of the invention.

What is claimed is:

1. A shield structure, comprising:
a shield frame electrically conductive and disposed around an electronic component mounted on a board top face of a circuit board, the shield frame having (i) a lower end positioned toward, and secured to, the board top face to conduct electricity to the circuit board, and (ii) an upper end opened, and positioned across from the lower end; and
an electrically conductive plate provided to the upper end of the shield frame, the electrically conductive plate (i) including a thin area thinned across from the electronic component and the shield frame, and (ii) electrically connected to the shield frame through the thin area.

2. The shield structure according to claim 1, wherein
the electrically conductive plate is a radiating plate or a reinforcing plate provided to a casing of the electronic device in the shield structure.

3. The shield structure according to claim 1, wherein
the electrically conductive plate includes a board-side-face opposing portion positioned across from one of board side faces of the circuit board, and
the shield frame has a side end opened, and positioned across from the board-side-face opposing portion, the side end being connected to the board-side-face opposing portion.

4. The shield structure according to claim 1, further comprising
a conductive flexible member provided to a connection electrically connecting the shield frame and the electrically conducting plate together.

5. The shield structure according to claim 1, wherein
in a connection electrically connecting the shield frame and the electrically conductive plate together, the upper end of the shield frame is inserted in a clearance formed in the electrically conductive plate, and the shield frame is fixed in the clearance with solder or a conductive adhesive.

6. An electronic device in the shield structure according to claim 1.
